(19) United States
(12) Patent Application Publication
(10) Pub. No.: US 2015/0102708 A1
(43) Pub. Date: Apr. 16, 2015

(54) PIEZOELECTRIC DEVICE AND METHOD OF FABRICATING THE SAME

(71) Applicant: Samsung Electro-Mechanics Co., Ltd., Suwon (KR)

(72) Inventors: Boum Seock KIM, Suwon (KR); Hui Sun PARK, Suwon (KR); Jung Wook SEO, Suwon (KR)

(73) Assignee: Samsung Electro-Mechanics Co., Ltd., Suwon (KR)

(21) Appl. No.: 14/142,100

(22) Filed: Dec. 27, 2013

(30) Foreign Application Priority Data
Oct. 14, 2013 (KR) 10-2013-0121792

(51) Int. Cl. H01L 41/083; H01L 41/313

(52) U.S. Cl. CPC H01L 41/083; H01L 41/313
USPC 310/365; 29/25.35

(57) ABSTRACT

There is provided a piezoelectric device including: a body portion having a plurality of piezoelectric layers stacked therein; and internal electrodes disposed in the body portion with at least one of the plurality of piezoelectric layers interposed therebetween and including a shrinkage inhibitor having at least one of a flake shape and a plate shape, wherein an angle formed by an interface between the internal electrode and the piezoelectric layer on which the internal electrode and the piezoelectric layer are in contact and a long side direction of the shrinkage inhibitor is 15° or less.

### CROSS-REFERENCE TO RELATED APPLICATION

This application claims the benefit of Korean Patent Application No. 10-2013-0121792 filed on Oct. 14, 2013, with the Korean Intellectual Property Office, the disclosure of which is incorporated herein by reference.

### BACKGROUND

The present disclosure relates to a piezoelectric device and a method of fabricating the same.

In recent portable electronic devices such as mobile phones, game consoles, e-books, and the like, vibrations have been used as silent signals notifying data or voice call reception, or as signals providing haptic feedback to a user inputting data to a portable electronic device via touch.

As a device generating vibrations, a piezoelectric device having a rapid response speed compared to existing vibration motors and able to be driven at various frequencies has been used.

The piezoelectric device, a device using a piezoelectric effect, refers to a device in which electric polarization occurs to form a difference in potentials when an external force is applied, deformation or deformation force is generated when a voltage is applied thereto. The piezoelectric device, also referred to as a piezoelectric element, is fabricated by using materials having excellent piezoelectric properties, such as crystals, tourmaline, Rochelle salt (potassium sodium tartrate), titanium acid barium, ammonium dihydrogen phosphate, and tartaric acid ethylene diamine.

In the piezoelectric device used as a vibration generator, the deformation or the deformation force generated by applying voltage to a piezoelectric material is used to generate vibrations.

In order to enlarge the deformation or the deformation force generated in the piezoelectric device, a plurality of thin piezoelectric layers having internal electrodes formed therein may be stacked to generate stronger vibrations. That is, in the case of the piezoelectric device fabricated by stacking the plurality of thin piezoelectric layers having the internal electrodes formed therein, at the time of applying the voltage to the device, an electric field is formed between two electrodes, and the structure of the device is deformed due to a dipole generated in the piezoelectric layer. Mechanical displacement may occur due to the deformation of the structure, and vibrations may thus be generated.

Since the displacement of the piezoelectric device increases in proportion to the electric field, a high voltage should be applied between the electrodes in order to obtain a high displacement.

Since the generation of the high voltage as an operating voltage may generally cause a big problem in a circuit, piezoelectric devices are generally fabricated in a manner in which the plurality of piezoelectric layers are stacked, and a thickness between the electrodes is decreased, such that a voltage may be maintained at the same level while having a higher electric field, whereby a large amount of displacement may occur.

For example, in the case of applying the same voltage to a piezoelectric device fabricated to have a single layer or to the piezoelectric device fabricated by stacking a plurality of layers, the piezoelectric device fabricated by stacking the plurality of layers may have a large amount of displacement occur at the same voltage as compared to the piezoelectric device fabricated to have a single layer.

However, in the case of a stacked piezoelectric device having internal electrodes and piezoelectric layers stacked therein in order to generate a larger amount of displacement, a warpage phenomenon of the device may occur even when the voltage is not applied to the device due to a difference between shrinkage rates of the internal electrode and the piezoelectric layer during a sintering process.

### RELATED ART DOCUMENT

(Patent Document 1) Korean Patent Laid-Open Publication No. 10-2012-0013273

### SUMMARY

An aspect of the present disclosure may provide a piezoelectric device capable of suppressing a warpage phenomenon and having improved performance, and a method of fabricating the same.

According to an aspect of the present disclosure, a piezoelectric device may include: a body portion having a plurality of piezoelectric layers stacked therein; and internal electrodes disposed in the body portion with at least one of the plurality of piezoelectric layers interposed therebetween and including a shrinkage inhibitor having at least one of a flake shape and a plate shape, wherein an angle formed by an interface between the internal electrode and the piezoelectric layer on which the internal electrode and the piezoelectric layer are in contact and a long side direction of the shrinkage inhibitor is 15° or less.

When a long side diameter of the shrinkage inhibitor is a and a thickness of the shrinkage inhibitor is b, 1/3≦b/a≦1/10 may be satisfied.

The internal electrode may contain the shrinkage inhibitor in an amount of 5 wt % to 20 wt %.

When a thickness of the internal electrode is Te and a thickness of the shrinkage inhibitor is b, b/Te≦1/5 may be satisfied.

A thickness of the internal electrode may be 3 μm or less.

A thickness of the shrinkage inhibitor may be less than that of the internal electrode.

A thickness of the shrinkage inhibitor may be 200 nm or less.

The shrinkage inhibitor may contain a perovskite-typed ceramic having an ABO₃ structure.

The shrinkage inhibitor may contain at least one selected from a group consisting of lead zirconate titanate and barium titanate.

The number of stacked internal electrodes may be 3 or more.

According to another aspect of the present disclosure, a method of fabricating a piezoelectric device may include: preparing a plurality of ceramic green sheets for forming piezoelectric layers; preparing a conductive paste for an internal electrode including a shrinkage inhibitor having at least one of a flake shape and a plate shape and a conductive powder; forming internal electrode patterns on the ceramic green sheets so that an angle formed by a long side of the shrinkage inhibitor and the ceramic green sheet is 15° or less by using the conductive paste for the internal electrode; forming a laminate by stacking the ceramic green sheets having the internal electrode patterns formed thereon; and forming a body portion including the piezoelectric layers and the internal electrodes by sintering the laminate.

When a long side diameter of the shrinkage inhibitor is a and a thickness of the shrinkage inhibitor is b, 1/3≦b/a≦1/10 may be satisfied.

The shrinkage inhibitor may be contained in an amount of 5 wt % to 20 wt % based on a solid content formed of the conductive powder and the shrinkage inhibitor.

When a thickness of the internal electrode is Te and a thickness of the shrinkage inhibitor is b, b/Te≦1/5 may be satisfied.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a piezoelectric device according to an exemplary embodiment of the present disclosure;

FIG. 2 is a cross-sectional view taken along line A-A′ of FIG. 1;

FIG. 3 is an enlarged view of a region P of FIG. 2; and

FIG. 4 is a flow chart illustrating a method of fabricating the piezoelectric device according to an exemplary embodiment of the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Piezoelectric Device

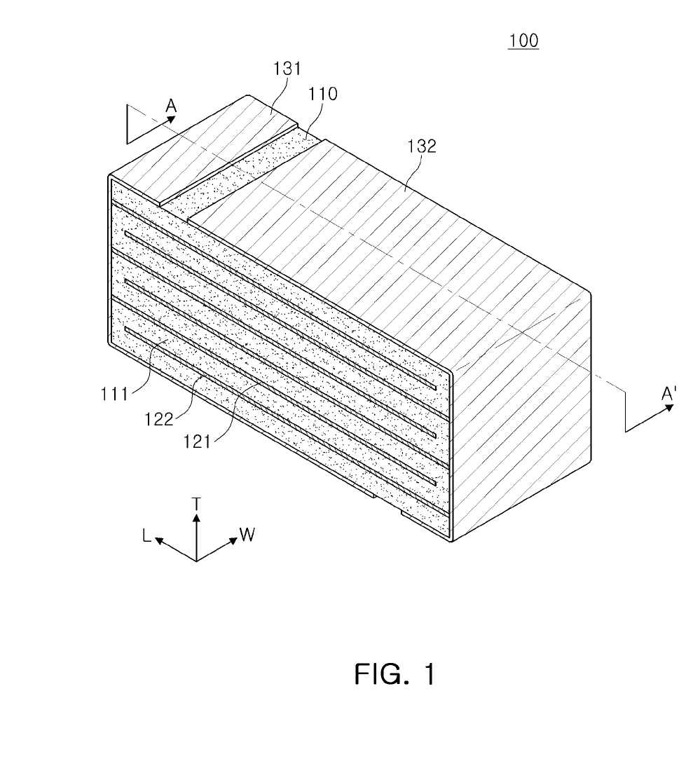

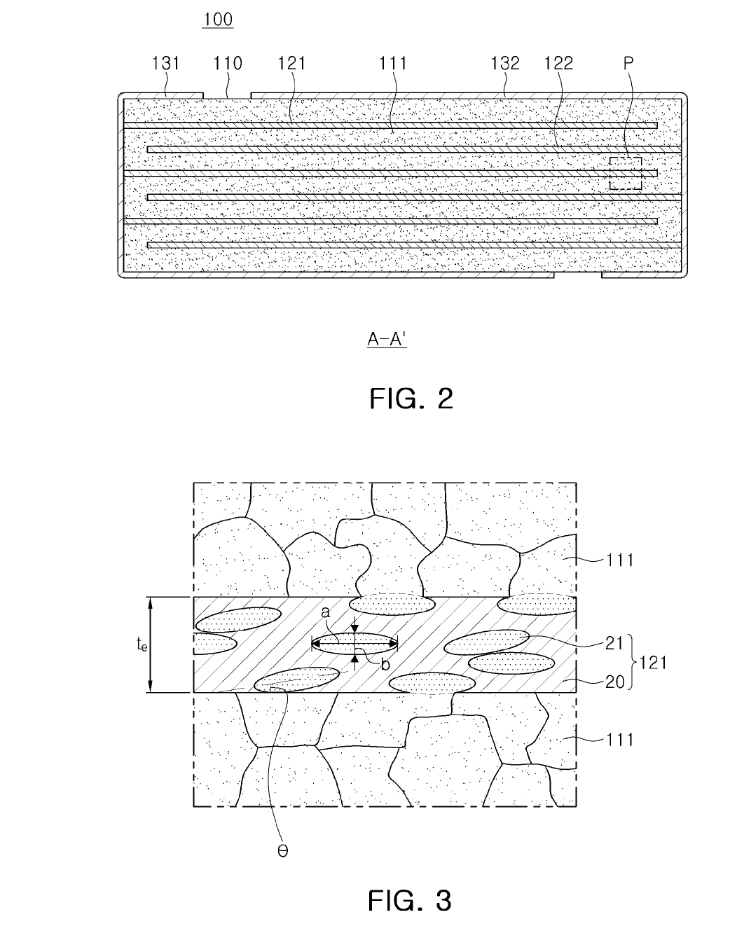

FIG. 1 is a perspective view schematically illustrating a piezoelectric device according to an exemplary embodiment of the present disclosure, and FIG. 2 is a cross-sectional view taken along line A-A′ of FIG. 1.

Referring to FIGS. 1 and 2, a piezoelectric device 100 according to the exemplary embodiment of the present disclosure may include a body portion 110 and external electrodes 131 and 132.

The body portion 110 may include a plurality of piezoelectric layers 111 and internal electrodes 121 and 122 disposed having at least one of the plurality of piezoelectric layers interposed therebetween.

In the exemplary embodiment of the present disclosure, a “length direction” of the body portion may be referred to as an “L” direction of FIG. 1, a “width direction” thereof may be referred to as a “W” direction of FIG. 1, and a “thickness direction” thereof may be referred to as a “T” direction of FIG. 1. Here, the “thickness direction” may be the same as a direction in which the piezoelectric layers are stacked, that is, a “stacking direction”.

The internal electrodes 121 and 122 may include first and second internal electrodes having different polarities from each other, wherein the first and second internal electrodes may be alternately disposed in the stacking direction.

The external electrodes may include first and second external electrodes, wherein the first and second external electrodes are electrically connected to the first and second internal electrodes, respectively.

The piezoelectric layer 111 may be formed by using a material capable of exhibiting a piezoelectric effect.

The piezoelectric effect refers to an effect in which, in the case of applying external force, electric polarization occurs to form a difference in potentials, and in the case of applying a voltage, deformation or a deformation force occurs.

The piezoelectric layer 111 may contain a perovskite-type material having an ABO3 structure, and may be fabricated by using at least one material selected from a group consisting of lead zirconate titanate and barium titanate or a mixture thereof, but the present disclosure is not limited thereto.

The first and second internal electrodes 121 and 122 may be formed by using a conductive paste including metal powders having excellent conductivity such as silver (Ag), gold (Au), copper (Cu) and a silver-lead (Ag—Pb) alloy and a shrinkage inhibitor.

The first and second internal electrodes 121 and 122 may be alternately interposed between the plurality of piezoelectric layers 111 so as to have different polarities from each other.

In order to obtain the piezoelectric effect, electric fields having different polarities are applied to the piezoelectric layer 111 to induce a dipole, thereby generating deformation or deformation force, so the first and second internal electrodes 121 and 122 are required to have different polarities from each other.

Since the first and second internal electrodes 121 and 122 are required to have different polarities from each other, the first internal electrode 121 may be electrically connected to the first external electrode 131 and the second internal electrode 122 may be electrically connected to the second external electrode 132.

FIG. 3 is an enlarged view of a region P of FIG. 2.

As shown in FIG. 3, the first and second internal electrodes 121 and 122 may contain a ceramic shrinkage inhibitor 21 to suppress shrinkage of the internal electrode and to improve adhesion strength with the piezoelectric layer 111 at the time of sintering.

That is, the first and second internal electrodes may include a conductive electrode part 20 and the shrinkage inhibitor 21.

Since the internal electrode and the piezoelectric layer have different shrinkage initiation temperatures and shrinkage rates from each other during the sintering process, in the case in which the shrinkage inhibitor is not added, the first and second internal electrodes may be significantly shrunk, and the piezoelectric layer may be less shrunk, such that the body portion becomes bent, or the internal electrode and the piezoelectric layer are separated from each other.

However, in the case in which the internal electrode contains the shrinkage inhibitor 21 as described in the exemplary embodiment of the present disclosure, the difference in the shrinkage rates between the internal electrode and the piezoelectric layer may be decreased, and the shrinkage inhibitor contained in the internal electrode may hinder the internal electrode from being shrunken in a length direction due to the adhesion between the shrinkage inhibitor contained in the internal electrode and the piezoelectric layer, such that a warpage phenomenon of the body portion may be suppressed. In addition, adhesion strength between the piezoelectric layer and the internal electrode may be increased.

Further, according to the exemplary embodiment of the present disclosure, the shrinkage inhibitor 21 may have at least one of a flake shape and a plate shape.

In order to improve the piezoelectric effect to increase the deformation or the deformation force, there are a method of applying an increased voltage to the first and second internal electrodes 121 and 122 and a method of thinning the internal electrodes 121 and 122 and the piezoelectric layer 111. However, the case in which the increased voltage is applied to the first and second internal electrodes 121 and 122 may have a limitation resulting from a failure of electronic equipment due to a power supply and high voltage of the portable electronic equipment. Therefore, the internal electrodes 121 and 122 and the piezoelectric layer 111 are required to be thinned.

Meanwhile, in the case in which a spherical inhibitor is added to the thin internal electrode in order to suppress the warpage phenomenon of the body portion and to increase the adhesion strength between the internal electrode and the piezoelectric layer, disconnection of the internal electrode may occur, or a thickness of the internal electrode may be increased, such that the internal electrode may not be thinned.

However, according to the exemplary embodiment of the present disclosure, since the shrinkage inhibitor contained in the internal electrode has at least one of a plate shape having a large difference between the length (long side) and the thickness or a flake shape, an area on which the shrinkage inhibitor and the piezoelectric layer are in contact is increased as compared to the spherical inhibitor, such that the warpage phenomenon of the body portion may be suppressed and a phenomenon in which the thickness of the internal electrode is increased by the addition of the shrinkage inhibitor may occur to a lesser degree.

According to the exemplary embodiment of the present disclosure, an angle formed by a long side direction of the shrinkage inhibitor 21 contained in the internal electrode and an interface between the internal electrodes 121 and 122 and the piezoelectric layer 111 (hereinafter, referred to as an angle θ) may be 15° or less.

In the case in which the angle formed by the shrinkage inhibitor 21 and the interface is 15° or less, the area on which the shrinkage inhibitor and the piezoelectric layer are in contact is increased such that the warpage phenomenon may be significantly suppressed, and the shrinkage inhibitor has a decreased influence on the thickness direction of the internal electrode such that the thickness of the internal electrode may not be increased.

However, in the case in which the angle formed by the shrinkage inhibitor and the interface is more than 15°, the area in which the shrinkage inhibitor and the piezoelectric layer are in contact is decreased, such that suppression of the shrinkage of the internal electrode and the warpage phenomenon may not be sufficient, and the long side may have an increased influence on the thickness direction of the internal electrode (which may affect at least a long side length*sin θ), whereby the thickness of the internal electrode may be increased.

In addition, according to the exemplary embodiment of the present disclosure, when a long side diameter of the shrinkage inhibitor 21 is a, and a thickness thereof is b, 1/3≦b/a≦1/10 may be satisfied.

The longest portion of the shrinkage inhibitor in the exemplary embodiment of the present disclosure may be defined as a long side. In particular, in the case in which the shrinkage inhibitor has a plate shape, the longest portion on a flat surface may be defined as the long side.

In the case in which b/a exceeds 1/3, the thin internal electrode may be difficult to achieve due to the increase in the thickness of the internal electrode caused by the addition of the shrinkage inhibitor, and since the interface at which the shrinkage inhibitor and the piezoelectric layer contact each other has a small area, the warpage phenomenon may be suppressed to a lesser degree. In the case in which b/a is less than 1/10, since the shrinkage inhibitor has an extremely long or flat shape, workability and productivity may be deteriorated at the time of fabricating and applying (printing) the internal electrode paste containing the shrinkage inhibitor, and a strength of the shrinkage inhibitor itself after sintering may be significantly decreased, such that the warpage phenomenon of the body portion may not be prevented.

The exemplary embodiment of the present disclosure may exhibit particularly excellent effects in the thin internal electrode, wherein the thickness of the internal electrode may be 3 μm or less.

In addition, according to the exemplary embodiment of the present disclosure, the internal electrode may contain the shrinkage inhibitor in an amount of 5 wt % to 20 wt %.

In the case in which the content of the shrinkage inhibitor is less than 5 wt %, the effect in which the warpage phenomenon of the body portion is suppressed and the adhesion strength between the internal electrode and the piezoelectric layer is improved may not be sufficient, and in the case in which the content of the shrinkage inhibitor is more than 20 wt %, the internal electrode may have deteriorated connectivity or increased thickness, and cost competitiveness may decrease due to an increase in material cost.

In addition, according to the exemplary embodiment of the present disclosure, the shrinkage inhibitor may be contained in the internal electrode so as not to penetrate through the internal electrode. More specifically, when the long side diameter of the shrinkage inhibitor is a, and an angle formed by the shrinkage inhibitor and the interface is θ, the thickness of the internal electrode may be greater than a*sin θ. More specifically, when the thickness of the internal electrode is Te and the thickness of the shrinkage inhibitor is b, b/Te≦1/5 may be satisfied. In the case in which the thickness of the shrinkage inhibitor satisfies b/Te≦1/5, the thickness of the internal electrode may not be increased, and the shrinkage inhibitor may be uniformly distributed on upper and lower surfaces, such that the warpage phenomenon of the body portion may be effectively suppressed.

The thickness of the shrinkage inhibitor may be 200 nm or less.

According to the exemplary embodiment of the present disclosure, the shrinkage inhibitor may contain a perovskite-typed ceramic having an ABO₃ structure, and may contain at least one selected from a group consisting of lead zirconate titanate and barium titanate, but the present disclosure is not limited thereto.

In addition, the shrinkage inhibitor may be formed of the same material as that of the piezoelectric layer.

In the case in which both of the piezoelectric layer and the shrinkage inhibitor contain a perovskite-typed ceramic having an ABO₃ structure, adhesion between the piezoelectric layer and the shrinkage inhibitor may be additionally strengthened due to the identical lattice structures. Therefore, the shrinkage of the internal electrode may be effectively suppressed and the warpage phenomenon of the body portion may be further suppressed. In particular, in the case in which the piezoelectric layer and the shrinkage inhibitor are formed of the same ceramic, the warpage phenomenon may be most effectively suppressed.

According to the exemplary embodiment of the present disclosure, the number of stacked piezoelectric layers and internal electrodes may be 3 or more.

### Method of Fabricating Piezoelectric Device

Hereinafter, a method of fabricating a piezoelectric device according to another exemplary embodiment of the present disclosure will be described.

In addition, descriptions which overlap with the above-described piezoelectric device in describing the method of fabricating the piezoelectric device according to the exemplary embodiment of the present disclosure will be omitted.

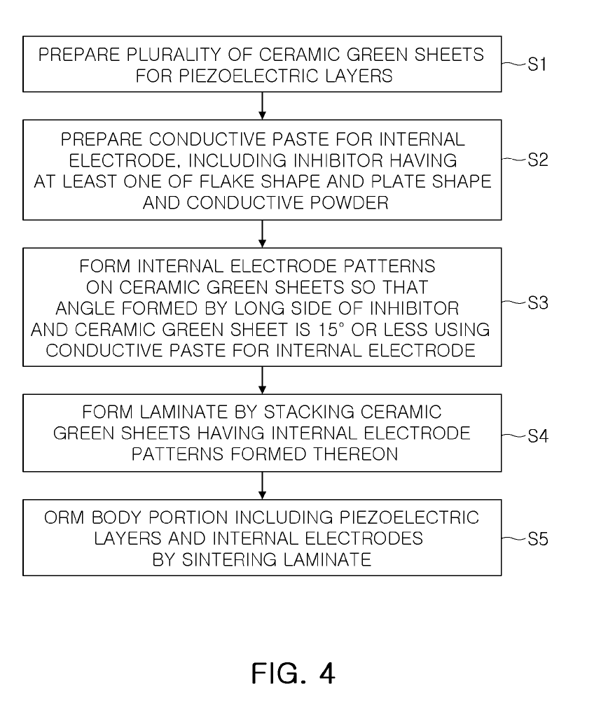

FIG. 4 is a flow chart illustrating a method of fabricating the piezoelectric device according to the exemplary embodiment of the present disclosure.

Referring to FIG. 4, the method of fabricating the piezoelectric device according to another exemplary embodiment of the present disclosure may include: preparing a plurality of ceramic green sheets for forming piezoelectric layers (S1); preparing a conductive paste for an internal electrode, including a shrinkage inhibitor having at least one of a flake shape and a plate shape and a conductive powder (S2); forming internal electrode patterns on the ceramic green sheets so that an angle formed by a long side of the shrinkage inhibitor and the ceramic green sheet is 15° or less by using the conductive paste for the internal electrode (S3); forming a laminate by stacking the ceramic green sheets having the internal electrode patterns formed thereon (S4); and forming a body portion including the piezoelectric layers and the internal electrodes by sintering the laminate (S5).

Initially in the method of fabricating the piezoelectric device according to the exemplary embodiment of the present disclosure, a slurry containing a piezoelectric powder such as lead zirconate titanate or barium titanate may be applied and dried to prepare a plurality of ceramic green sheets, forming the piezoelectric layer.

The ceramic green sheet may be fabricated by mixing piezoelectric powder, a binder, and a solvent to prepare the slurry, and forming the slurry as a sheet having a designed thickness.

Then, a conductive paste for an internal electrode containing the conductive powder and the shrinkage inhibitor may be prepared. The shrinkage inhibitor powder may contain a ceramic material, and may use the same material as that of a dielectric material contained in the ceramic green sheet.

The shrinkage inhibitor may be contained in an amount of 5 wt % to 20 wt % based on a solid content formed of the conductive powder and the shrinkage inhibitor, and may have at least one shape of a flake shape and a plate shape.

In addition, when a long side diameter of the shrinkage inhibitor is a and a thickness of the shrinkage inhibitor is b, 1/3≦b/a≦1/10 may be satisfied.

Then, the conductive paste for the internal electrode may be applied to the ceramic green sheet to form the internal electrode patterns, and the plurality of ceramic green sheets having the internal electrode patterns formed thereon may be stacked to prepare a laminate.

Next, the laminate may be sintered to prepare a body portion including the piezoelectric layers and the internal electrodes.

When a thickness of the internal electrode is Te and a thickness of the shrinkage inhibitor is b, b/Te≦1/5 may be satisfied.

In addition, according to the exemplary embodiment of the present disclosure, the method may further include forming the body portion and then forming external electrodes on an external surface of the body portion to be connected to the internal electrodes.

### Experimental Example

The following Table 1 shows whether a warpage defect occurs due to a warpage phenomenon of the body portion and an increasing rate in a thickness of an internal electrode depending on an angle θ formed by an interface at which the internal electrode and the piezoelectric layer are in contact and a long side direction of the shrinkage inhibitor contained in the internal electrode of the piezoelectric device. The increasing rate of the thickness of the internal electrode was obtained by measuring a ratio of the thickness of the internal electrode according to Experimental Example to a thickness of an internal electrode not having the shrinkage inhibitor added thereto.

TABLE 1

| | | | Increasing Rate (%) of Thickness |
|---|---|---|---|
| Sample | ⊖ (°) | Warpage Defect | of Internal Electrode |
| 1 | 0 | OK | 0 |
| 2 | 5 | OK | 5 |
| 3 | 10 | OK | 10 |
| 4 | 13 | OK | 13 |
| 5 | 15 | OK | 15 |
| 6* | 17 | NG | 20 |
| 7* | 20 | NG | 30 |

*Comparative Example
OK: Ratio of the shortest length to the maximum length in a length direction of the body portion is 0.9 or more
NG: Ratio of the shortest length to the maximum length in a length direction of the body portion is less than 0.9

It may be seen from Table 1 above that in Samples 1 to 5, which are cases in which the angle θ formed by the shrinkage inhibitor and the interface between the internal electrode and the piezoelectric layer is 15° or less, a change in the increasing rate of the thickness of the internal electrode depending on an increase in θ is not significant, but in the case in which the angle θ formed by the shrinkage inhibitor and the interface between the internal electrode and the piezoelectric layer is greater than 15°, the increasing rate of the thickness of the internal electrode depending on the increase in θ is rapidly increased.

The following Table 2 shows data obtained by evaluating performance and workability of the piezoelectric device depending on a ratio of a long side diameter a to a thickness b of the shrinkage inhibitor.

TABLE 2

| Sample | b/a | Performance of Device | Workability |
|---|---|---|---|
| 8* | 1/20 | X | X |
| 9 | 1/10 | ◯ | ◯ |
| 10 | 1/7 | ◯ | ◯ |
| 11 | 1/5 | ◯ | ◯ |
| 12 | 1/3 | ◯ | ◯ |
| 13* | 1/2 | X | ◯ |
| 14* | 1 | X | ◯ |

*Comparative Example
◯: Satisfactory Performance of Device and Workability
X: Unsatisfactory Performance of Device and Workability

As seen in Table 2 above, in the case in which b/a is more than 1/3, it may be difficult to achieve the thin internal electrode due to the increase in the thickness of the internal electrode by addition of the shrinkage inhibitor, and since the interface on which the shrinkage inhibitor and the piezoelectric layer are in contact has a small area, the warpage phenomenon of the body portion may not be suppressed, such that the performance of the device may deteriorate. In the case in which b/a is less than 1/10, since the shrinkage inhibitor has an extremely long or flat shape, the workability and productivity may deteriorate at the time of preparing and applying the paste for the internal electrode including the shrinkage inhibitor, and strength of the shrinkage inhibitor itself after sintering may be extremely decreased, such that the warpage phenomenon of the body portion may not be prevented and the performance of the device may deteriorate.

As set forth above, according to exemplary embodiments of the present disclosure, a piezoelectric device suppressing warpage phenomenon and having improved performance, and a method of fabricating the same, may be provided.

While exemplary embodiments have been shown and described above, it will be apparent to those skilled in the art that modifications and variations could be made without departing from the spirit and scope of the present disclosure as defined by the appended claims.

What is claimed is:

1. A piezoelectric device comprising:
a body portion having a plurality of piezoelectric layers stacked therein; and
internal electrodes disposed in the body portion with at least one of the plurality of piezoelectric layers interposed therebetween and including a shrinkage inhibitor having at least one of a flake shape and a plate shape,
wherein an angle formed by an interface between the internal electrode and the piezoelectric layer on which the internal electrode and the piezoelectric layer are in contact and a long side direction of the shrinkage inhibitor is 15° or less.

2. The piezoelectric device of claim 1, wherein when a long side diameter of the shrinkage inhibitor is a and a thickness of the shrinkage inhibitor is b, 1/3≦b/a≦1/10 is satisfied.

3. The piezoelectric device of claim 1, wherein the internal electrode contains the shrinkage inhibitor in an amount of 5 wt % to 20 wt %.

4. The piezoelectric device of claim 1, wherein when a thickness of the internal electrode is Te and a thickness of the shrinkage inhibitor is b, b/Te≦1/5 is satisfied.

5. The piezoelectric device of claim 1, wherein a thickness of the internal electrode is 3 μm or less.

6. The piezoelectric device of claim 1, wherein a thickness of the shrinkage inhibitor is less than that of the internal electrode.

7. The piezoelectric device of claim 1, wherein a thickness of the shrinkage inhibitor is 200 nm or less.

8. The piezoelectric device of claim 1, wherein the shrinkage inhibitor contains a perovskite-typed ceramic having an ABO₃ structure.

9. The piezoelectric device of claim 1, wherein the shrinkage inhibitor contains at least one selected from a group consisting of lead zirconate titanate and barium titanate.

10. The piezoelectric device of claim 1, wherein the number of stacked internal electrodes is 3 or more.

11. A method of fabricating a piezoelectric device, the method comprising:
preparing a plurality of ceramic green sheets for forming piezoelectric layers;
preparing a conductive paste for an internal electrode including a shrinkage inhibitor having at least one of a flake shape and a plate shape and a conductive powder;
forming internal electrode patterns on the ceramic green sheets so that an angle formed by a long side of the shrinkage inhibitor and the ceramic green sheet is 15° or less by using the conductive paste for the internal electrode;
forming a laminate by stacking the ceramic green sheets having the internal electrode patterns formed thereon; and
forming a body portion including the piezoelectric layers and the internal electrodes by sintering the laminate.

12. The method of claim 11, wherein when a long side diameter of the shrinkage inhibitor is a and a thickness of the shrinkage inhibitor is b, 1/3≦b/a≦1/10 is satisfied.

13. The method of claim 11, wherein the shrinkage inhibitor is contained in an amount of 5 wt % to 20 wt % based on a solid content formed of the conductive powder and the shrinkage inhibitor.

14. The method of claim 11, wherein when a thickness of the internal electrode is Te and a thickness of the shrinkage inhibitor is b, b/Te≦1/5 is satisfied.
